(19) United States
(12) Patent Application Publication
(10) Pub. No.: US 2015/0092788 A1
(43) Pub. Date: Apr. 2, 2015

(54) INPUT-OUTPUT MODULE

(71) Applicants: Michael J. Kennedy, Spring, TX (US); David M. Koonce, Cypress, TX (US); Felix L. Erales, Cypress, TX (US); Charles R. Hanna, Houston, TX (US)

(72) Inventors: Michael J. Kennedy, Spring, TX (US); David M. Koonce, Cypress, TX (US); Felix L. Erales, Cypress, TX (US); Charles R. Hanna, Houston, TX (US)

(21) Appl. No.: 14/396,694

(22) PCT Filed: Apr. 26, 2012
(86) PCT No.: PCT/US2012/035311

§ 371 Date: Oct. 23, 2014

(51) Int. Cl. G06F 1/18; H05K 7/14

(52) U.S. Cl. CPC G06F 1/183; H05K 7/1422; H05K 7/1438; H05K 7/1457
USPC 370/419; 361/679.4; 361/679.32

(57) ABSTRACT

A base circuit board (80, 280) has a mid-plane connector (82, 282) for connecting the base circuit board (80, 280) to a mid-plane (26, 226) connected to a server board (32, 232). An ethernet input/output port (84, 284) on the base circuit board (80, 280) facilitates communication across the base circuit board (80, 280) to the server board (32, 232).

### BACKGROUND

Server systems generally include a chassis having an interconnecting circuit board, such as a backplane or a mid-plane, that connects one or more server circuit boards to other server system components such as hard drives, power supplies and the like. Changing an input-output architecture and associated cabling of the server system to accommodate a new server circuit board may be difficult and costly.

### BRIEF DESCRIPTION OF THE DRAWINGS

FIG. 1 is a schematic illustration of an example server system.

FIG. 2 is a schematic illustration of an example adapter of the server system of FIG. 1.

FIG. 3 is a schematic illustration of another example adapter of the server system of FIG. 1.

FIG. 4 is a schematic illustration of an example input-output module for the server system of FIG. 1.

FIG. 5 is a flow diagram of an example method that may be carried out by the server system of FIG. 1.

FIG. 6 is a flow diagram of another example method that may be carried out by the server system of FIG. 1.

FIG. 7 is a flow diagram of another method that may be carried out by the server system of FIG. 1.

FIG. 8 is a perspective view of an example implementation of the server system of FIG. 1.

FIG. 9 is a perspective view of the server system of FIG. 8 with portions omitted for purposes of illustration.

FIG. 10 is a top view of the server system of FIG. 9.

FIG. 11 is another perspective view of the server system of FIG. 8 with portions omitted for purposes of illustration.

FIG. 12 is a rear elevational view of the server system of FIG. 8.

FIG. 13 is a perspective view of an example adapter of the server system of FIG. 8.

FIG. 14 is a top view of the adapter of FIG. 13 and an example server board for the server system of FIG. 8.

FIG. 15 is a top view of the adapter and the server board of FIG. 14 connected to one another.

FIG. 16 is a front view of the connected adapter and server board of FIG. 15.

FIG. 17 is a schematic illustration of the adapter of FIG. 13.

FIG. 18 is a schematic illustration of an example input-output module of the server system of FIG. 8.

FIG. 19 is a rear perspective view of the input-output module of FIG. 18.

FIG. 20 of the top view of the input-output module of FIG. 18.

FIG. 21 is a rear perspective view of the server system of FIG. 8 with some portions omitted for purposes of illustration.

FIG. 22 is a top view of an example adapter card and option card connected to an input-output module of the server system of FIG. 8.

### DETAILED DESCRIPTION OF THE EXAMPLE EMBODIMENTS

FIG. 1 schematically illustrates an example server system 20. Server system 20 facilitates use of different server circuit boards with a single chassis or interconnecting circuit board. Server system 20 further facilitates the exchange or replacement of one server circuit board in the server system with a different server circuit board having a different interface. As will be described hereafter, server system 20 utilizes an input-output module 36 that facilitates modularity and adaptability of inputs and outputs for server system 20. The input-output module 36 facilitates the exchange, service or upgrade of a server circuit board 32 with fewer, if any, changes to the input-output architecture or layout including the associated cabling.

Server system 20 comprises enclosure 24, mid-plane 26, memory device backplane 28, internal memory devices 30, server circuit board 32, server adapter 34, input-output module 36 and modular control auxiliary or daughter cards 38, 40. Enclosure 24 and mid-plane 26 form chassis 42 for receiving and being connected to the remaining components of server system 20. Enclosure 24 comprises an outer casing, housing and the like which encloses and supports mid-plane 26 as well as the other components of server system 20. Mid-plane 26 comprises a circuit board including electrically conductive traces and electronic components by which power and data signals are transmitted or routed between those components connected to mid-plane 26. Although illustrated as including mid-plane 26, in other implementations with other architectures or layouts, server system 20 may alternatively use a backplane or other circuit board for interconnecting components of server system 20.

Memory device backplane 28 comprises a circuit board upon which internal memory devices 30 are removably mounted for use by server system 20. Memory device backplane 28 includes electrical traces and electronic components to connect such internal memory devices to mid-plane 26 and facilitates multiplexing of data or communication to and from each of internal memory devices 30. Memory device backplane 28 includes connectors 44 and 46. Connectors 44 are supported or mounted to backplane 28 and facilitate connection of internal memory devices 30 to backplane 28. Connector 46 comprises a connector, such as an electronic plug, extending from backplane 28 to connect to a corresponding connector or port of mid-plane 26. Although illustrated as comprising a single memory device backplane, in other implementations, server system 20 may include multiple memory device memory device backplanes. Although schematically illustrated as supporting two internal memory devices 30, in most other implementations, memory device memory device backplane 28 may support well more than two internal memory devices 30.

Internal memory devices 30 comprise devices for storing and retrieving digital information, such as computer data, that are releasably mounted or connected to memory device backplane 28. Internal memory devices 30 comprise one or more of nonvolatile, random access, magnetic, digital or data storage devices. In one implementation, internal memory devices 30 comprise hard disk drives or disk drives, rigid or hard rotating discs or platters coated with magnetic material, wherein magnetic head is read and write data to such surfaces. In another implementation, internal memory devices 30 may comprise other non-transient computer-readable mediums, such as solid state memory devices. In some implementations, internal memory devices 30 may be fixed to memory device backplane 28.

Server circuit board 32, also referred as a server board, comprises a circuit board supporting server components for use by server system 20. Server circuit board 32 carries server or blade components such as processors, connectors, server-storage array controllers, ethernet controllers, dual in-line memory devices (DIMMs), switches, routers, gateways and input-output interfaces or ports. Server circuit board 32 along with the server blade components (processors, memory and the like) form a server or node. As will be described hereafter, in some implementations, some components of server board 32 may be omitted where such components are now provided by adapter circuit board 34, input-output module 36 and/or modular control daughter cards 38, 40. Server circuit board 32, and its components, facilitate the use of server system 20 to host one or more services or computational tasks on behalf of clients. Depending upon the type of services provided by the server formed by server circuit board 32, server system 20 may comprise an application server, a catalog server, the communication server, a fax server, a database server, a file server, a game server, a name server, a print server, a proxy server, a sound server, a web server and the like.

As schematically shown by FIG. 1, server circuit board 32 comprises a bus slot 50 and a connector 52. Bus slot 50 comprises an input-output interface to in the form of a slot to receive a card or riser. In one implementation, bus slot 50 comprises a peripheral component interconnect express PCIe bus slot. In other implementations, bus slot 50 may utilize other present or future developed bus or interface configurations. In other implementations, the server circuit board 32 may have 2 or more bus slots 50 that connect to the server adapter 34.

Connector 52 comprises an interface to facilitate releasable or removal connection of server circuit board 32 to mid-plane 26 or another interconnecting board (such as a backplane) for the supply of power and the communication of data to and from server circuit board 32 and its components. In the example illustrated, connector 52 may or may not be specifically configured to mate with a corresponding connector or connection portion of mid-plane 26. In the example illustrated, connector 52 is not utilized as connection with mid-plane 26 is facilitated by adapter 34. In some implementations, connector 52 may be omitted.

Adapter 34 comprises a custom interface between server circuit board 32 and an interconnect circuit board, such as mid-plane 26. FIG. 2 schematically illustrates adapter 34 distinct from system 20. Adapter 34 may be provided as part of system 20 or may be provided separately from system 20 after prior acquisition of system 20 to facilitate use of different server circuit boards, such as server circuit board 32′ having a differently configured connector interface 52′.

As shown by FIG. 2, adapter 34 comprises adapter circuit board 56, riser 58 and connector 66. Adapter circuit board 56 comprises a printed circuit board carrying and supporting riser 58 and connector 66 while including electrical traces (such as the one electrical trace 68 schematically shown in FIG. 2) electrically connecting riser 58 and connector 66 to one another and to other electrical components that may be carried by adapter circuit board 56.

Riser 58 comprises a printed circuit board or card projecting from adapter circuit board 56 which includes an edge connector having electrical contacts or connections for being received within bus slot 50 of server circuit board 32. Riser 58 includes electrical traces for distributing and routing data and power signals from bus slot 50 of server circuit board 32 to adapter circuit board 56. In one implementation, riser 58 comprises a PCIe card. In one implementation, riser 58 has an edge opposite to the edge connector that is permanently fixed or attached to adapter circuit board 56. In another implementation, adapter circuit board 56 may itself include a bus slot, wherein riser 58 has two edge connectors, with one of the edge connectors position in the bus slot of the adapter circuit board 56 and the other of the edge connectors receivable within bus slot 50 of server circuit board 32. Riser 58 facilitates connection of adapter circuit board 56 to server circuit board 32 using an existing bus slot 50 on server circuit board 32. Riser 58 facilitates the use of adapter 34 with a variety of different server circuit boards.

In one implementation, riser 58 comprises a card extending perpendicular to adapter circuit board 56. In another implementation, riser 58 comprises a card extending parallel to but spaced from adapter circuit board 56. In the example illustrated, adapter 34 is illustrated as including a single riser 58 for use with a server circuit board developed to use an Advance Micro Devices (AMD) processor architecture. However, in other implementations, adapter 34 may include a plurality of risers 58. For example, adapter 34 may include a pair of risers 58 for being simultaneously received within a pair of bus slot 50 where the circuit board 32 has an INTEL processor architecture.

Connector 66 comprises an interface for connecting adapter 34, and in particular, adapter circuit board 56, to an interconnecting circuit board, such as mid-plane 26. Connector 66 mates and connects with a corresponding connector portion of mid-plane 26. In one implementation, connector 66 is configured so as to connect to mid-plane 26 using the same connecting portion of mid-plane 26 that would otherwise be connected to an interface or connector of a server circuit board 32. In other implementations, connector 66 may be configured to be connected to other connectors of mid-plane 26.

As shown by FIG. 1, adapter 34 interfaces between server circuit board 32 and mid-plane 26. As a result, server circuit board 32 may be utilized in server system 20 even in those circumstances where connector 52 of server circuit board 32 is not configured for connecting with a particular connection architecture or connector of mid-plane 26. Moreover, as indicated by arrows 70, adapter 34 facilitates the replacement of server circuit board 32 with a different server circuit board 32′ having a different connector 52′. As a result, server circuit board 32 may be replaced with an updated or more technically advanced server circuit board 32 while continuing use of many, if not all, of the other components of server system 20. In addition to facilitating easier exchange or replacement or server circuit board 32, adapter 34 facilitates mixing of various types of server boards to a single mid-plane 26 in a single server system 20.

FIG. 3 schematically illustrates adapter 74, an example of another adapter that may be utilized in place of adapter 34 in server system 20. Adapter 74 is similar to adapter 34 except that adapter 74 additionally includes repeaters 76. Repeaters 76 (also sometimes referred to as re-drivers) comprise electronic circuit chips carried by adapter circuit board 56 which receive signals that are received by riser 58 and re-drive such signals such that signals are passed on to connector 66. Repeaters 76 repeat signals to preserve signal integrity over large transmission distances. Repeaters 76 preserve signal integrity despite the longer signal transmission distances resulting from the use of adapter 74 where such signals are transmitted across riser 58 and across adapter circuit board 56 prior to reaching mid-plane 26.

In one implementation, repeaters 76 comprise a PCIe driver. In one example, repeaters 76 each comprise a low-power, four-lane repeater with four stage input equalization and output de-emphasis driver, referred to as a 6 DS80PCI800 and commercially available from TEXAS INSTRUMENTS. In one implementation, adapter 74 comprises 6 6 DS80PCI800 chips, accommodating 24 PCIe communication lanes in both directions. Each lane is composed of a transmit and receive pair of differential lines composed of four wires or signal paths to provide a full-duplex byte stream in both directions simultaneously. In other implementations, adapter 74 may comprise a greater or fewer of such repeaters 76, accommodating a different number of communication lanes. In other implementations, adapter 34 may include repeaters 76 having other configurations, accommodating a same or a different number of such communication lanes.

In one implementation, adapter 74 additionally includes one or more reference clock buffers 77 for re-driving a reference clock. In one implementation, such buffers may comprise three zero-delay buffer supports commercially available under the identification ICS9 DB102. Each buffer 77 is driven by a differential SRC output pair from an ICS CK410/CK505-compliant main clock to attenuate jitter on an input clock to maximize performance. In one implementation, adapter 74 comprises three of such chips. In other implementations, adapter 74 may omit such clock buffers or may utilize other clock buffers or repeaters.

Input-output module 36 comprises a device that facilitates modularity and adaptability of inputs and outputs for server system 20. Input-output module 36 facilitates the exchange, service or upgrade of server circuit board 32 by relocating input-output interfaces and controllers for server circuit board 32 onto a separately mounted structure such that the server circuit board 32 may be exchanged, serviced or upgraded with fewer, if any, changes to the input-output architecture or layout including the associated cabling. In other words, server circuit board 32 may be upgraded, repaired or redeployed with reduced disturbance to an existing external cabling system without a loss of input-output, such as a storage array (i.e. Smart Array Controller), an Ethernet, Infiniband or other Input-Output module connected interface component. In some implementations, server system 20 facilitates replacement of a server circuit board 32 without imposing the burden of replacing other server system infrastructure such as server-storage array controllers, ethernet controllers or ports and the like.

In addition, module 36 further facilitate changes to the input-output for a server circuit board 32 independent of the server circuit board 32. In other words, the input-output components for a particular server circuit board may be upgraded or exchanged while the existing server circuit board 32 remains in place. By relocating input-output interfaces and controllers from server circuit board 32, additional area or space is provided along server circuit board 32 for enhanced airflow and enhanced cooling of the processors or other heat generating components on server circuit board 32.

As shown by FIG. 1, module 36 comprises base circuit board 80, connector 82, input-output port 84, input-output controller 86 and auxiliary connectors 90, 92. Base circuit board 80 comprise a printed circuit board supporting one or more input-output interfaces and controllers as well as electrical traces for routing signals across circuit board 80. Connector 82 comprises a high-frequency mid-plane connection system interface releasably connecting circuit board 80 to mid-plane 26. Connector 82 comprises

Input-output port 84 comprise a port by which input-output signals may be transmitted to and from module 36 from external sources through components on the base assembly (module 36) or by another assembly attached to the module 36. In the example illustrated, input-output 84 comprises one or more ports located at a rear 96 of enclosure 24. In one implementation, input-output port 84 comprises an ethernet input-output port. Examples of such an ethernet input-output port 84 include, but are not limited to, 10/100/1000 base T ethernet and 10 gigabyte ethernet ports. In another implementation, input-output port 84 comprises a 40 GB Infiniband port. In yet other implementations, input-output 44 may comprise other input-output ports having a capacity of at least 10 GB. In one implementation, port 84 may comprise an SFP+ module a QSFP module or both each capable of supporting 10 Gb per second data transfer rate along with 10/100/1000 base-T ethernet. In another implementation port 84 may comprise an SFP+ module capable of 10 Gb/sec Ethernet along with a QSFP module capable of 40 Gb/Sec INFINIBAND. In yet other implementations, port 84 may comprise an InfiniBand port which is a switched fabric communication link. In yet other implementations, port 84 may comprise other presently available or future available ports are connectors supporting high rates of data transfer.

Input-Output controller 86 comprises a communication protocol device to transfer and format data received through port 84 to the server chip set or in reverse from the chip set to port 84. In other implementations, controller 86 may comprise other controllers or switches.

Auxiliary connectors 92 comprise connectors extending from base circuit board 80 to facilitate connection of modular control daughter cards 38, 40. Connectors 92 are offset from one another on circuit board 80 to facilitate concurrent connection of each of modular control daughter cards 38, 40. As will be described hereafter, modular control daughter cards 38, 40 provide additional or supplemental componentry relocated from server control board 32 for enhanced modularity.

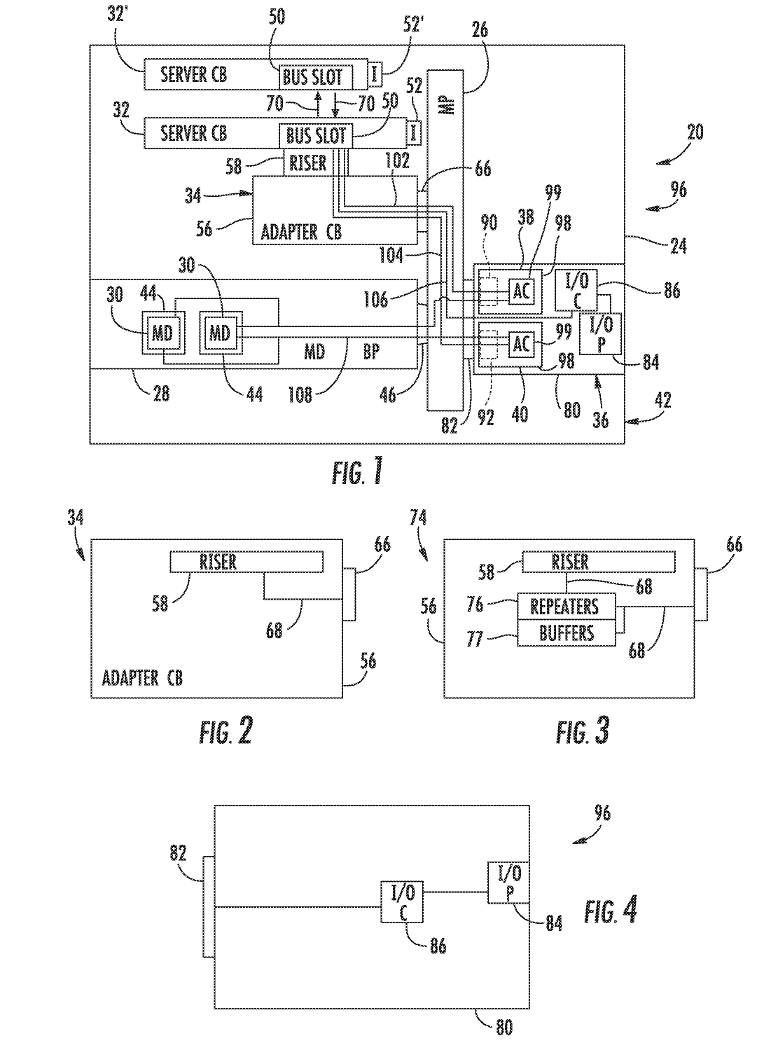

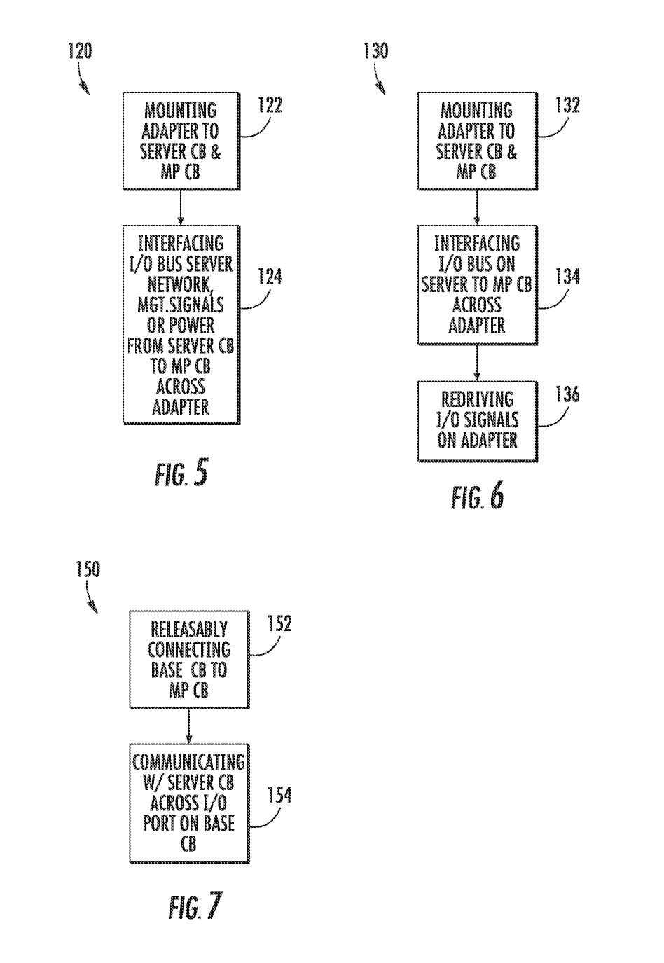

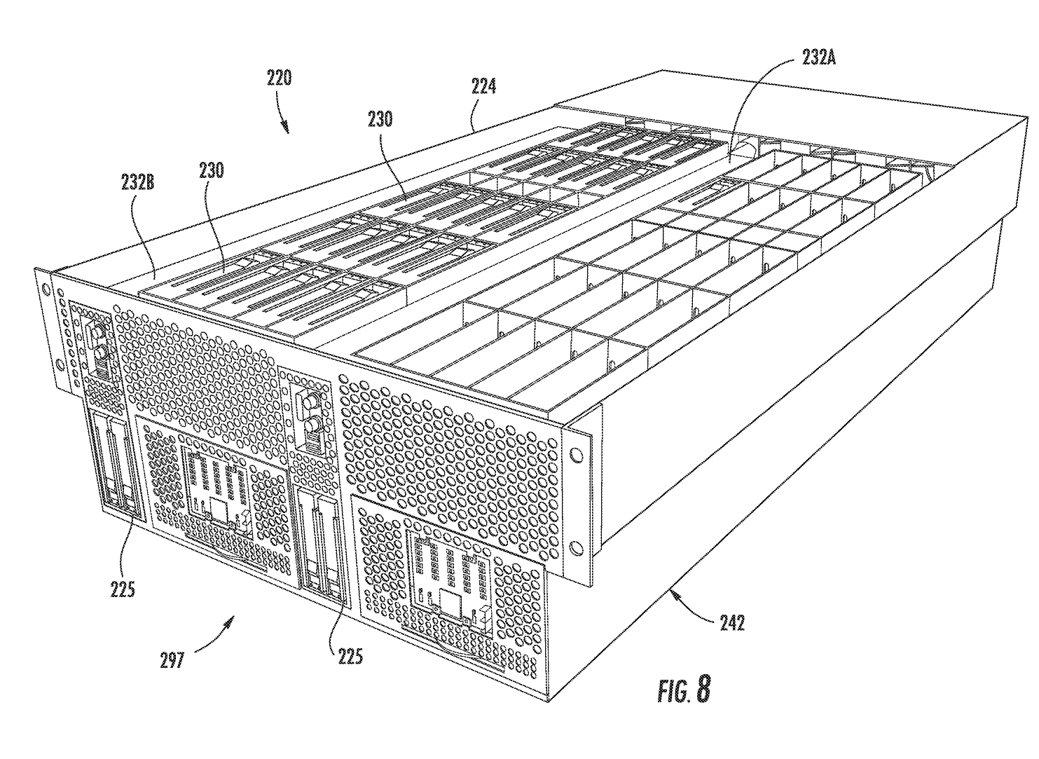

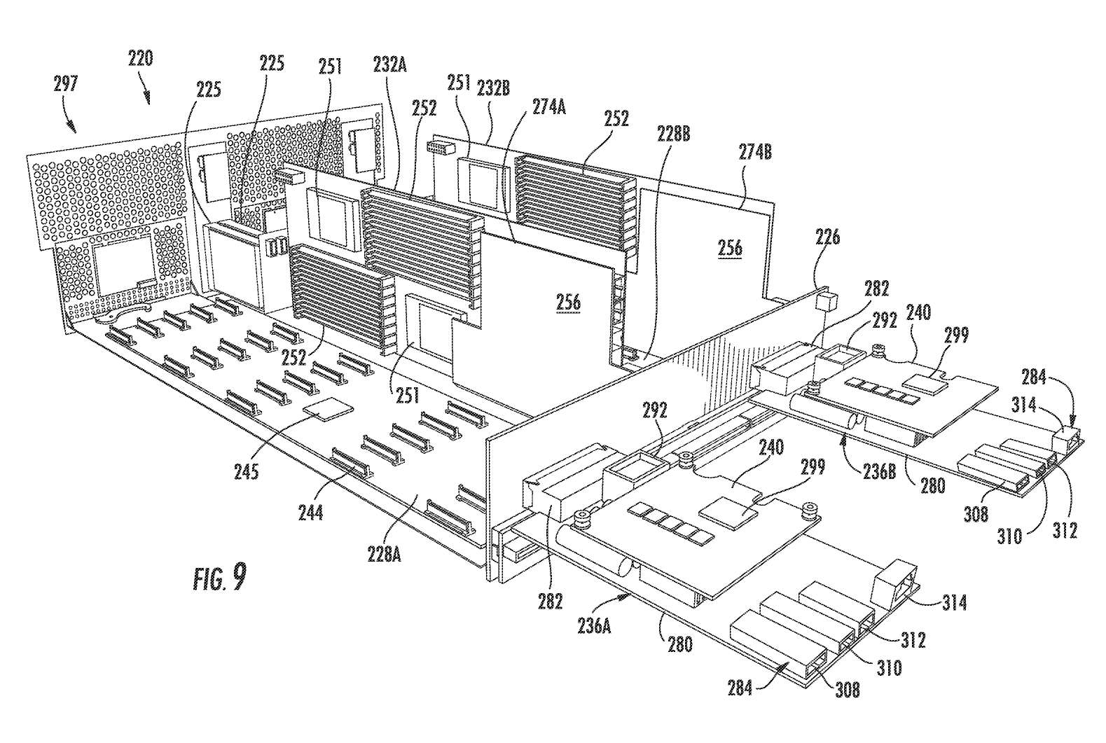

As shown by FIG. 4, in other implementations, auxiliary connectors 90, 92 may be omitted where modular control daughter cards 38, 40 are also omitted. FIG. 4 schematically illustrates module 96, an alternative example of module 36 which may be utilized in place of module 36 shown in FIG. 1. Like module 36, module 96 may be provided as part of system 20 or may be provided separately from system 20 after prior acquisition of system 20 to facilitate use of different input-output arrangements or the subsequent replacement of server circuit board 32. In some implementations, server circuit board 32 may omit such input-output ports and controllers which are now relocated to module 36, allowing for less complex and less expensive server circuit boards. In yet other implementations, such input-output ports and controllers may remain on the existing server circuit board 32, but not be utilized.

As shown by FIG. 1, modular control daughter cards 38, 40 connect to module 36 via connectors 90 and 92, respectively. Although illustrated as connected to circuit board 80 in a side-by-side arrangement, in other implementations, connectors 90 and 92 may project from circuit board 80 by different heights, wherein cards 38, 40 are connected to circuit board 80 in an at least partially stacked arrangement. In one implementation, each of daughter cards 38, 40 is substantially identical to the other. Each card 38, 40 comprises a circuit board 98 and a server-storage array controller 99. Circuit board 98 comprises a printed circuit board having electrical traces along which data signals and power are transmitted.

In one implementation, daughter cards 38, 40 each comprise a PCIe mezzanine card manufactured to the IEEE P1386.1 standard. In such an implementation, connectors 90, 92 each comprise a mezzanine connector. In other implementations, daughter cards 38, 40 may be manufactured pursuant other standards and may have other configurations.

Server-storage array controller 99 comprises a device that manages physical disk drives and present such drives to server circuit board 30 as logical units. In the example illustrated, server-storage array controller 99 may manage a portion of internal memory devices 30. In one implementation, server-storage array controller 99 comprises a RAID (redundant arrays of independent disks) controller. In other implementations, server-storage array controller 99 make comprise other forms of devices for managing internal memory devices 30 and interfacing between such internal memory devices 30 and server circuit board 32.

Although module 36 is illustrated as including a pair of connectors 90, 92 for connection to a pair of cards 38, 40, in other implementations, module 36 may be connected to a greater or fewer of such cards 38, 40. For example, in some implementations, a single card 38, 40 may be configured to manage all of drives 30. In such an implementation, one of cards 38, 40 may be omitted. In other implementations, server system 20 may include multiple server circuit boards connected to mid-plane 26. In such an implementation, that 36 may include multiple cards 38, 40, with each card 38, 40 serving a different server circuit board.

As schematically shown in FIG. 1, in one implementation, server system 20 includes or forms a plurality of PCIe communication lanes 102 extending from server-storage controller 98 on the auxiliary or daughter card 38, across base circuit board 80, across mid-plane 26 and to server circuit board 32. In the example illustrated, server system 20 additionally includes or forms a plurality of PCIe communication lanes 104 extending from server-storage controller 99 on the auxiliary or daughter card 40, across base circuit board 80, across mid-plane 26 and to server circuit board 32. In the example illustrated, server system 20 additionally includes or forms a plurality of PCIe communication lanes 106 extending from ethernet input-output port 84, across base circuit board 80, across mid-plane 26 and to server circuit board 32. In one implementation, each of the plurality of lanes 102, 104 and 106 comprise eight PCIe lanes. As schematically shown in the illustrated example, service system 20 additionally comprises a plurality of serial attached SCSI (SAS) lanes 108 extending from server-storage array controller 99 to memory device backplane 28 and internal memory devices 30. In other implementations, server system 20 may be provided with other sets of PCIe lanes and SAS lanes having other pathway connections.

Overall, module 36 (or module 96) offers several advantages or benefits. First, because module 36 offloads or relocates input-output port 84 and input-output controller 86 from server circuit board 32 to circuit board 80, module 36 provides enhanced flexibility and modularity to facilitate upgrading, repairing or redeployment of server circuit board 32, provides a mechanism for input-output modification independent of server circuit board 32 and offers enhanced cooling are providing more space along server circuit board 32.

Second, because module 36 provides a modular or distributed architecture, module 36 may offer high-frequency input and output (greater than 10 GB) with improved signal integrity. In particular, because the chipset data transfer physical layer used to directly connect to the input-output protocol devices (serial attached SCSI (SAS), Serial ATA (SATA), 10 G Ethernet, Infiniband) is close to the external connect point (port 84), signal integrity is enhanced. Because module 36 offers a wider port count to storage interface devices, module 36 offers improved bandwidth for storage interfaces such as SAS.

Third, module 36 may reduce the overall cost for server system 20. For example, since circuit server board 32 may omit input-output ports and controllers which are now provided on module 36, circuit server boards may be less complex and less expensive. Repeating devices for the 10 GB input-output ports may further be omitted from the server circuit board. By using a PCIe to 10 GB Ethernet and Infiniband (IB) adapter or controller 86, IB repeating devices may also be omitted from the server circuit board.

FIG. 5 is a flow diagram illustrating an example method 120 that may be implemented by server system 20 with either of adapters 34 or 74. In particular, as indicated by step 122, adapter 34 is mounted to server circuit board 32 and to mid-plane circuit board 26. As indicated by step 124, once adapter 34 is interconnected between server circuit board 32 and mid-plane 26, adapter 34 is utilized to interface at least one of an input-output bus, a server network, management signals or power from server circuit board 32 to mid-plane 26. As a result, adapter 34 facilitates use of different server circuit boards 32 with mid-plane 26.

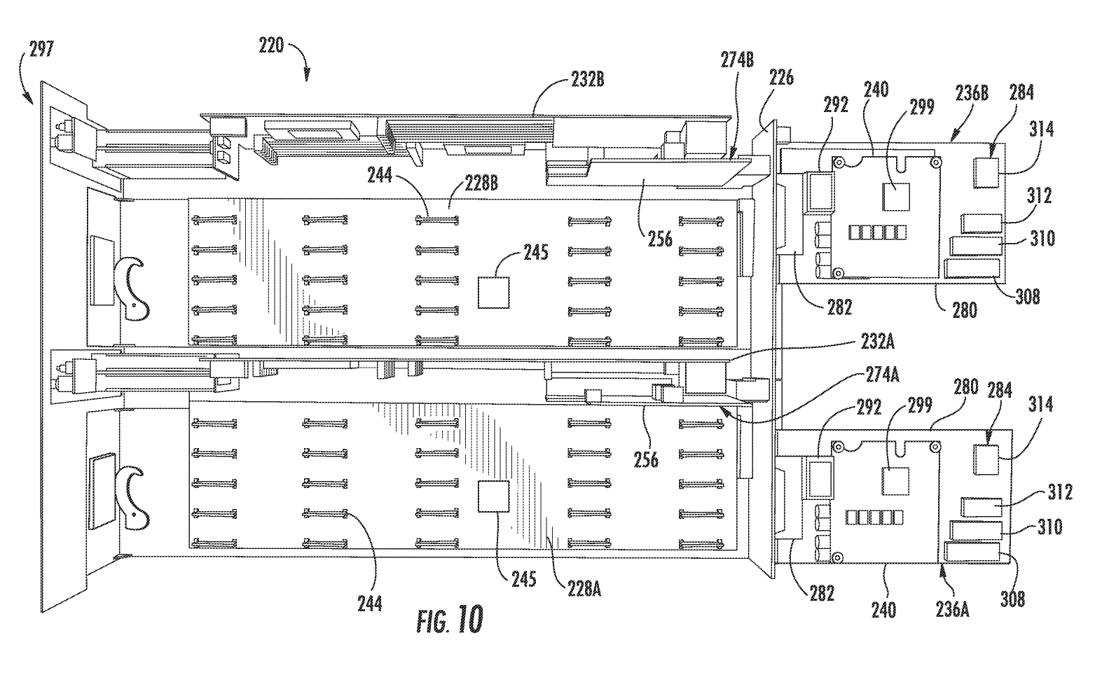

FIG. 6 is a flow diagram illustrating an example method 130 that may be implemented by server system 20 with adapter 74. As indicated by step 132, adapter 74 is mounted to server circuit board 32 and to mid-plane circuit board 26. As indicated by step 134, once adapter 74 is interconnected between server circuit board 32 and mid-plane 26, adapter 74 is utilized to interface the input-output bus on server circuit board 32 to mid-plane circuit board 26. As indicated by step 136, repeaters 26 on adapter 34 further re-drive or repeat input-output signals on adapter 74 to preserve signal integrity or reduce signal degradation.

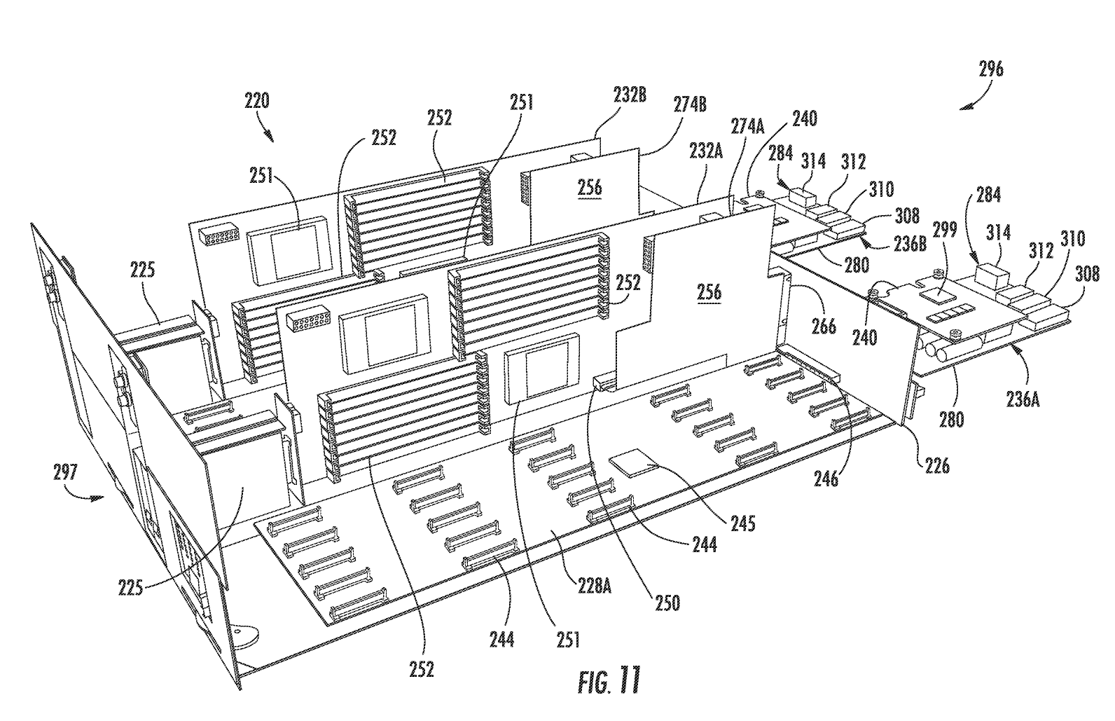

FIG. 7 is a flow diagram of an example method 150 that may be carried out by server system 20. As indicated by step 152, a circuit board 80 of module 36 is releasably connected to mid-plane circuit board 26. As indicated by step 154, once module 36 (or module 96) is connected to mid-plane 26, data signals are communicated to server circuit board 32 across the input-output port 84 provided on a circuit board 80.

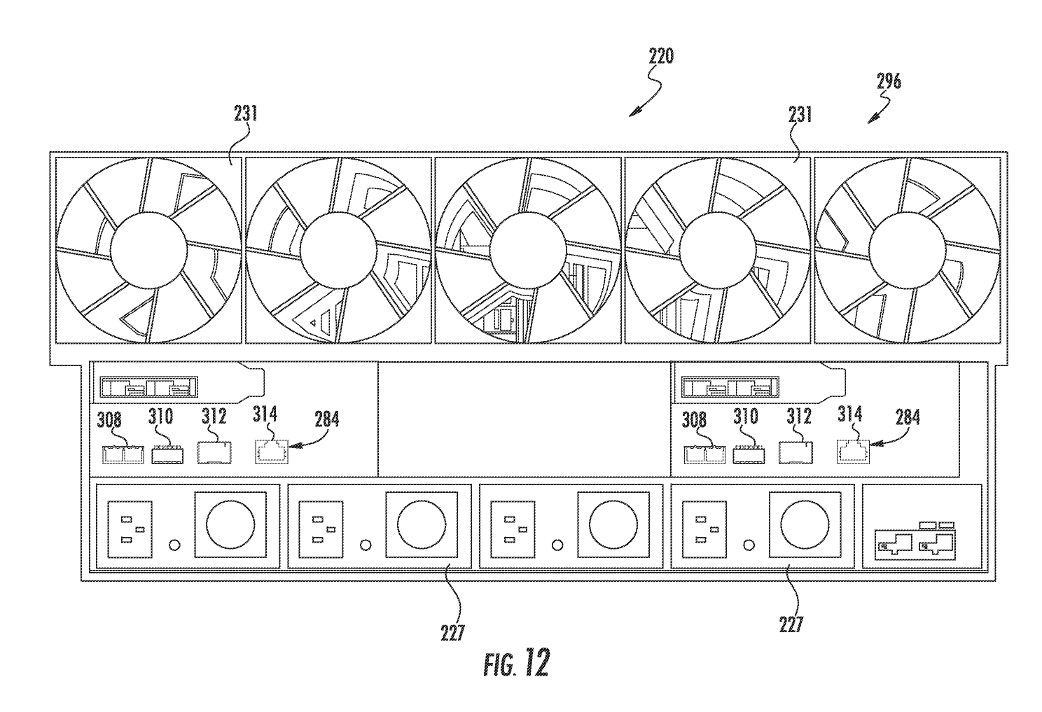

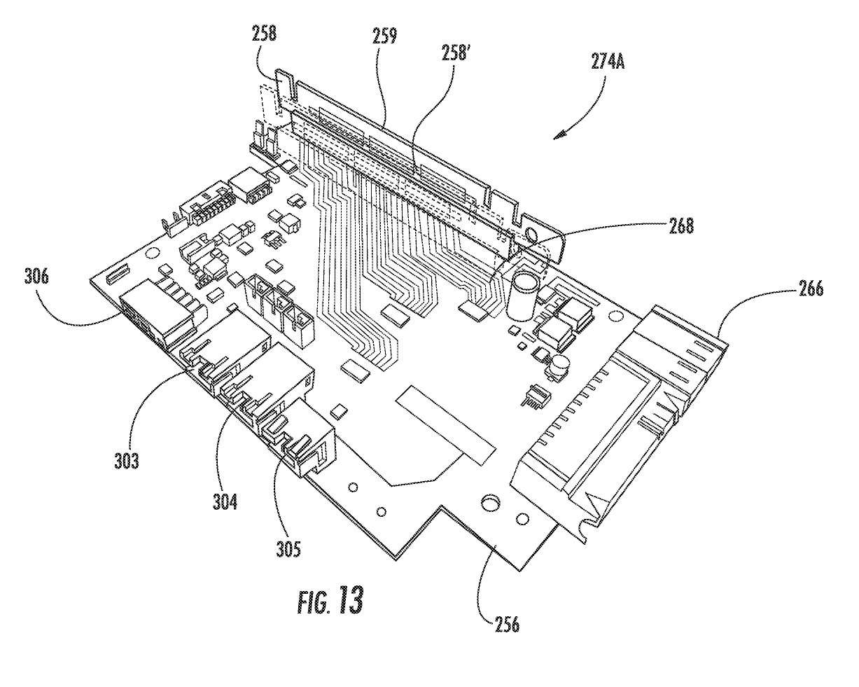

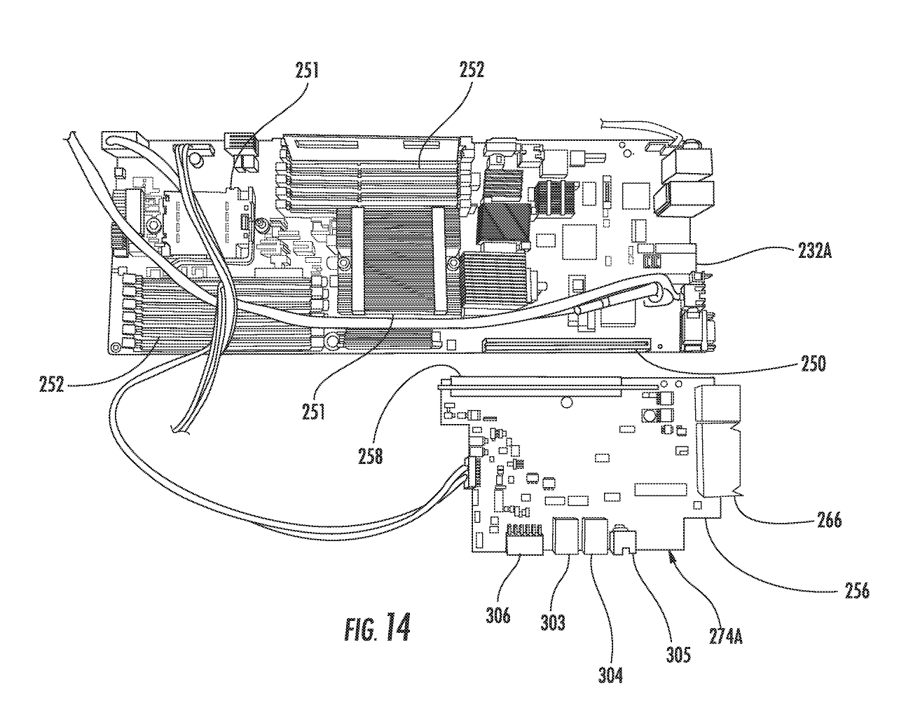

FIGS. 8-12 illustrate server system 220, an example implementation of server system 20. Server system 220 comprises enclosure 224, external storage drives 225, mid-plane 226 (shown in FIG. 9-11), power supplies 227 (shown in FIG. 12), memory device backplanes 228A, 228B (collectively referred to as backplanes 228) (shown in FIGS. 9-11), internal memory devices 230 (shown in FIG. 8), fans 231 (shown in FIG. 12), server circuit boards 232A, 232B (collectively referred to as server circuit boards 232), server adapters 274A, 274B (collectively referred to as server adapters 274), input-output modules 236A, 236B (collectively referred to as modules 236) and modular control auxiliary or daughter cards 240 (shown in FIGS. 9-11). Enclosure 224 and mid-plane 226 form chassis 242 for receiving and being connected to the remaining components of server system 220. Enclosure 224 comprises an outer casing, housing and the like which encloses and supports mid-plane 226 as well as the other components of server system 220. Mid-plane 226 comprises a circuit board including electrically conductive traces and electronic components by which power and data signals are transmitted or routed between those components connected to mid-plane 226. Although illustrated as including mid-plane 226, in other implementations with other architectures or layouts, server system 220 may alternatively use a backplane or other circuit board for interconnecting components of server system 220.

External storage drives 225 comprise external drives, such as hard disk drives, solid state drives and the like which are accessible external to chassis 224. External storage drives 225 are connected to an associated server circuit board 232. In the example illustrated, storage drives 225 are accessible at a front end 297 of server system 220 and enclosure 242. In some implementations, storage drives 225 may be omitted.

Power supplies 227 are located at a rear 296 of server system 220 and include interfaces for connection to external power sources such as an AC outlet. Power supplies 227 convert and deliver power at appropriate voltages to fans 231 and to the remaining components of server system 220.

Memory device backplanes 228 each comprises a circuit board upon which internal memory devices 30 are removably mounted for use by server system 220. Memory device backplane 228 includes electrical traces and electronic components to connect such memory devices to mid-plane 226 and facilitates multiplexing of data or communication to and from each of internal memory devices 30. Memory device backplane 228 includes connectors 244, expander rule 245 and mid-plane connector 246. Connectors 244 are supported or mounted to backplane 228 and facilitate connection of hard drives 230 to backplane 228. Connector 246 comprises a connector, such as an electronic plug, extending from backplane 228 to connect to a corresponding connector or port of mid-plane 226. Although illustrated as comprising two memory device backplanes 228A and 228B, in other implementations, server system 220 may include more than two memory device backplanes. Although each backplane 228 is illustrated as including 30 connectors 244, in other implementations, backplanes 228 may include other numbers of connectors 244 for supporting other numbers of memory devices 230.

Memory devices 230 comprise devices for storing and retrieving digital information, such as computer data that are releasably mounted or connected to memory device backplane 228. Memory devices 230 comprise one or more of nonvolatile, random access, magnetic, digital or data storage devices. In one implementation, memory devices 230 comprise hard drives—rigid or hard rotating discs or platters coated with magnetic material, wherein magnetic head is read and write data to such surfaces. In another implementation, memory devices 230 may comprise other non-transient computer-readable mediums, such as solid state memory devices. In some implementations, memory devices 230 may be fixed to memory device backplane 228.

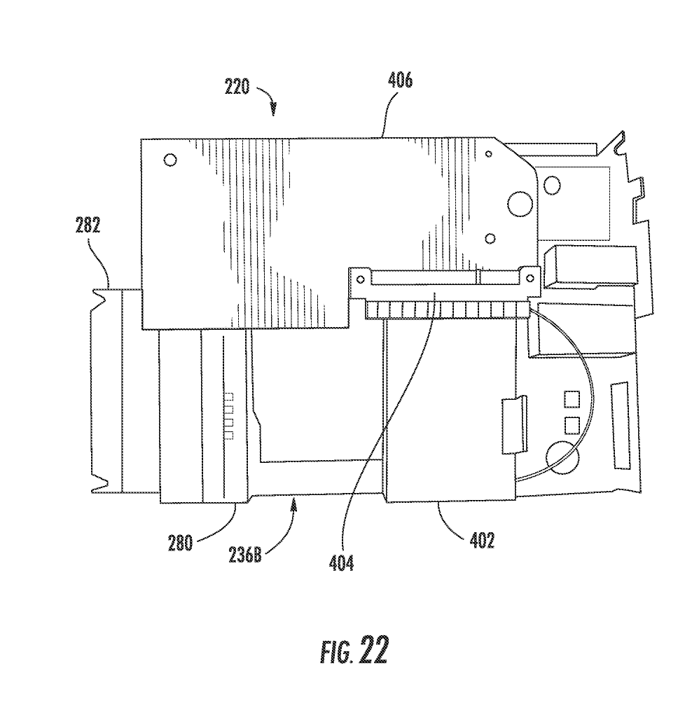

Fans 231 are located at rear 296 of server system 20 and create airflow through server system 220 to cool internal components of server system 20 such as processors on server circuit boards 232. As shown by FIG. 21, fans 231 and power supplies 227 sandwich input-output modules 236 therebetween at rear 296. As a result, efficient use of available space within enclosure 224 is achieved.

Server circuit board 232, also referred as a server board, comprises a circuit board supporting server components (processors, memory and connectors) which, together, form a server or computing node for use by server system 220. Server circuit board 232 carries server or blade components such as processors, connectors, server-storage array controllers, ethernet controllers, dual in-line memory devices (DIMMs), switches, routers, gateways and input-output interfaces or ports. As will be described hereafter, in some implementations, some components of server board 232 may be omitted where such components are now provided by adapter circuit board 274, input-output module 236 and/or modular control daughter cards 240. Server circuit board 232, and its components, facilitate the use of server system 220 to host one or more services or computational tasks on behalf of clients. Depending upon the type of services provided by the server formed by server circuit board 232, server system 220 may comprise an application server, a catalog server, the communication server, a fax server, a database server, a file server, a game server, a name server, a print server, a proxy server, a sound server, a web server and the like.

As shown by FIG. 11, server circuit board 232 comprises bus slot 250, processors 251 and memory slots 252. Although not illustrated, in some implementations, server circuit board 232 may additionally include an unused connector that another environments is configured to be connected to an inner connector board, such as mid-plane 226. Bus slot 250 comprises an input-output interface to in the form of a slot to receive a card or riser. In one implementation, bus slot 250 comprises a peripheral component interconnect express PCIe bus slot. In other implementations, bus slot 250 may utilize other present or future developed bus or interface configurations.

Processors 251 comprise processing units that perform the services of server system 220. Memory slots 252 comprise slots for receiving memory modules, such as dual in-line memory modules (DIMMs). In other implementations, server circuit board 232 may carry fewer or greater number of processors, memory slots and memory. Although not illustrated, server circuit board 232 may support other components such as heat sinks, fixed memory units and other electronic circuitry. In other implementations, server circuit board 232 may carry and utilize any of a variety of memory or processors.

Adapter 274 comprises a custom interface between server circuit board 232 and an interconnect circuit board, such as mid-plane 226. Adapter 274 may be provided as part of system 220 or may be provided separately from system 220 after prior acquisition of system 220 to facilitate use of different server circuit boards having a differently configured mid-plane connector interface.

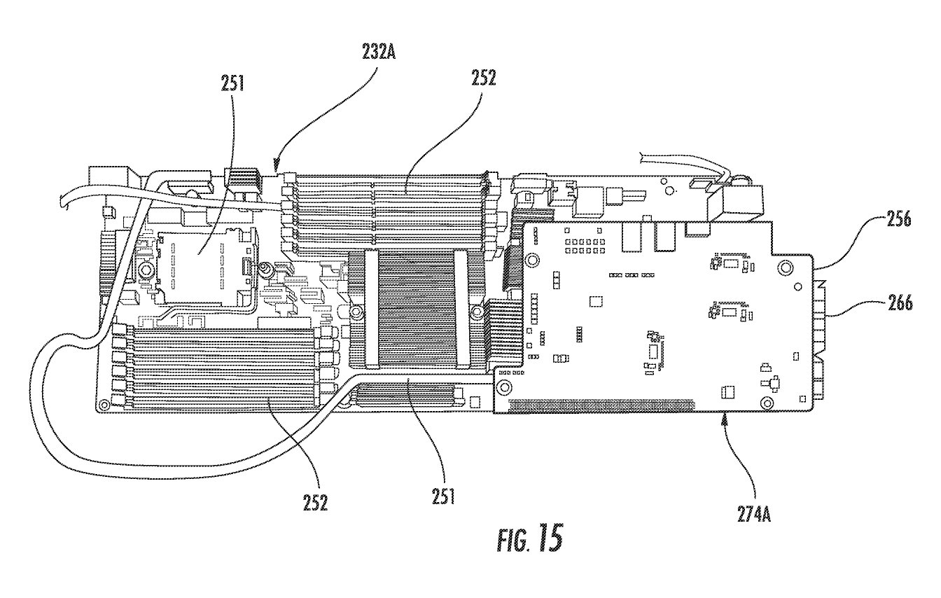

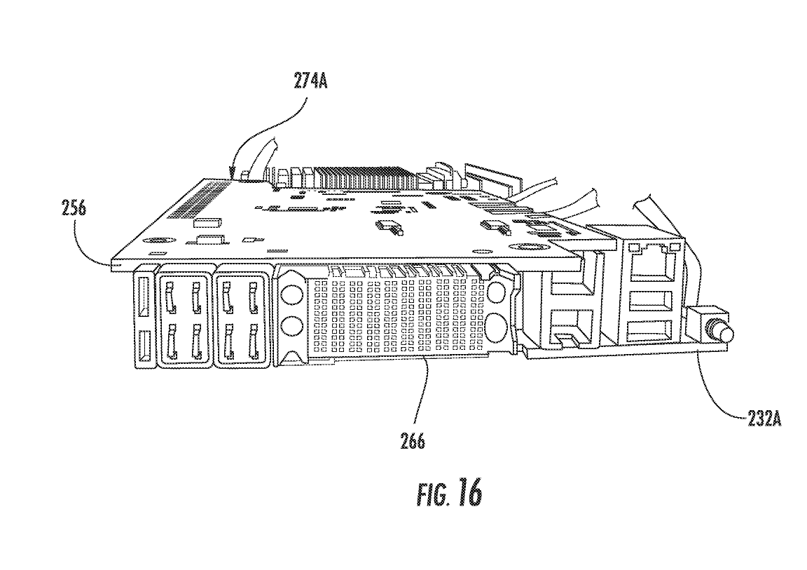

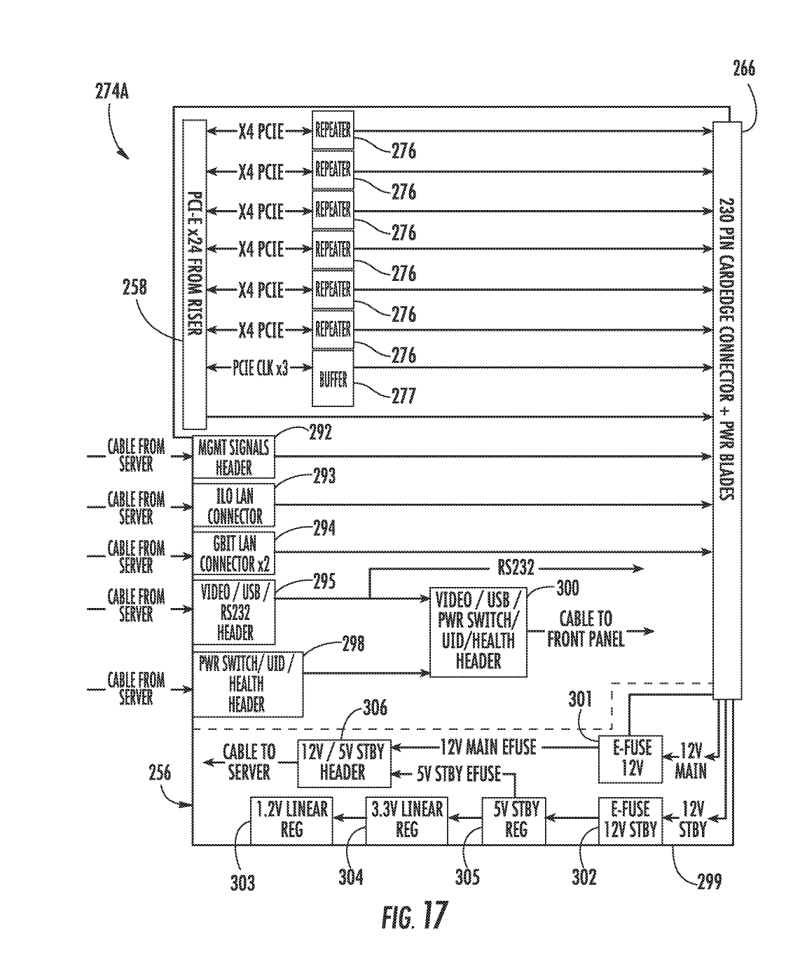

FIGS. 13-16 illustrate a detailed example of one of adapters 274. FIG. 14 illustrates one of adapters 274 exploded away from and adjacent to one of server boards 232. FIGS. 15 and 16 illustrate adapter 274 connected to server circuit board 232. As shown by FIGS. 13-16, adapter 274 comprises adapter circuit board 256, riser 258 and connector 266. Adapter circuit board 256 comprises a printed circuit board carrying and supporting riser 258 and connector 266 while including electrical traces 268 electrically connecting components on circuit board 256 to one another.

Riser 258 comprises a printed circuit board or card projecting from adapter circuit board 256 which includes an edge connector 259 having electrical contacts or connections for being received within bus slot 250 of server circuit board 232. Riser 258 includes electrical traces for distributing and routing data and power signals from bus slot 250 of server circuit board 232 to adapter circuit board 256. In one implementation, riser 258 comprises a PCIe card. In one implementation, riser 258 has an edge opposite to the edge connector that is permanently fixed or attached to adapter circuit board 256. In another implementation, adapter circuit board 56 may itself include a bus slot, wherein riser 258 has two edge connectors, with one of the edge connectors position in the bus slot of the adapter circuit board 256 and the other of the edge connectors receivable within bus slot 250 of server circuit board 32. Riser 258 facilitates connection of adapter circuit board 256 to server circuit board 32 using an existing bus slot 50 on server circuit board 232. Riser 258 facilitates the use of adapter 274 with a variety of different server circuit boards.

In one implementation, riser 258 comprises a card extending perpendicular to adapter circuit board 56. In another implementation, riser 258 comprises a card extending parallel to but spaced from adapter circuit board 256. In the example illustrated, adapter 274 is illustrated as including a single riser 258 for use with server circuit board such as provided by ADVANCE MICRO DEVICES. However, in other implementations, adapter 34 may include a plurality of risers 258. For example, with some server circuit boards or server boards commercially provided by INTEL, adapter 274 may include a pair of risers 258 (the second riser 258′ being shown in broken lines in FIG. 13) for being simultaneously received within a pair of bus slots 250 on such a server circuit board 232.

Connector 266 comprises an interface for connecting adapter 274, and in particular, adapter circuit board 256, to an interconnecting circuit board, such as mid-plane 226. Connector 266 mates and connects with a corresponding connector portion of mid-plane 226. In one implementation, connector 266 is configured so as to connect to mid-plane 226 using the same connecting portion of mid-plane 226 that would otherwise be connected to an interface or connector of a server circuit board 232. In other implementations, connector 266 may be configured to be connected to other connectors of mid-plane 226.

FIG. 17 is a schematic illustration or block diagram of one example of adapter 274. As shown by FIG. 17, adapter 274 comprises circuit board 256, riser 258, connector 266, signal repeaters 276, clock repeaters or buffers 277, rear signal transfer connectors 292, 293, 294, front signal transfer connectors 295, 298 and power control scheme or system 299. Circuit board 256, riser 258 and connector 266 are each described above.

Repeaters 276 comprise electronic circuit chips carried by adapter circuit board 256 which receive signals that are received by riser 258 and re-drive such signals before such signals are passed on to connector 266. Repeaters 276 repeat signals to preserve signal integrity over large transmission distances. Repeaters 276 preserve signal integrity despite the longer signal transmission distances resulting from the use of adapter 274 where such signals are transmitted across riser 258 and across adapter circuit board 256 prior to reaching mid-plane 226.

In one implementation, repeaters 276 comprise a PCIe driver. In one example, repeaters 276 each comprise a low-power, eight-lane repeater with four stage input equalization and output de-emphasis driver, referred to as a DS80PCI800 and commercially available from TEXAS INSTRUMENTS. In one implementation, adapter 274 comprises 6 DS80 pci402 chips, accommodating 24 PCIe communication lanes in both directions. Each lane is composed of a transmit and receive pair of differential lines composed of four wires or signal paths to provide a full-duplex byte stream in both directions simultaneously. In other implementations, adapter 274 may comprise a greater or fewer of such repeaters 276, accommodating a different number of communication lanes. In other implementations, adapter 274 may include repeaters 276 having other configurations, accommodating a same or a different number of such communication lanes.

In the illustrated example, adapter 274 additionally comprise one or more reference clock buffers 277 for re-driving a reference clock. In one implementation, buffers 277 comprise three zero-delay buffer supports commercially available under the identification ICS9 DB102. Each driver buffer support is driven by a differential SRC output pair from an ICS CK410/CK505-compliant main clock to attenuate jitter on an input clock to maximize performance. In one implementation, adapter 274 comprises three of such chips.

Rear signal transfer connectors 292, 293, 294 comprise connectors or headers that connect to cables extending from server circuit board 232. Connectors 292, 293, 294 transfer or route signals from server circuit board 32, across adapter circuit board 256 to connector 266 and to mid-plane 226 for connection to external ports. Connectors to 92, 293, 294 reduce cabling or cabling clutter within enclosure 224 and simplify exchange of server circuit board 232. In the example illustrated, connector 292 is configured to connect to the cable transmitting management signals for the server circuit board 232. Connector 293 is connectable to a cable from server circuit board 232 to receive signals pertaining to server management (ILO). Connector 294 comprises a pair of connectors connectable to a pair of cables from server circuit board 232 for transmitting 1 gigabyte data signals between server circuit board 232 and two 1 GB ethernet external ports at the rear 296 of enclosure 224.

Front signal transfer connectors 295, 298 comprise connectors or headers which are connectable to cables from server circuit board 232 which are to be routed to a front 297 of enclosure 224. Connector 295, 298 transfer or route signals from server circuit board 32, across adapter circuit board 256 to another connector or header 300 which is connectable to another cable that is connected to ports proximate to the front 297 of enclosure 224. Connectors 295, 298 reduce cabling or cabling clutter within enclosure 224 and simplify exchange of server circuit board 232. In the example illustrated, connector 295 comprises a video/USB/RS232 (a serial port for binary single-ended data and control signals connecting between a DTE (Data Terminal Equipment) and a DCE (Data Circuit-terminating Equipment) connector for transmitting such signals. Connector 298 comprises a power switch and user interface diagnostic (UID) health connector for transmitting signals from corresponding switches or controls at the front of enclosure 224 to server circuit board 232 for turning on or off circuit board 232 and for providing information regarding the health of server circuit board 232. In other implementations, additional or fewer of such connectors and corresponding routings may be provided on adapter 274.

Power control scheme or system 299 transmits or delivers electrical power across adapter 274 to an electrical cable that is connected to server circuit board 232. In the example illustrated, power control system 290 additionally monitors or facilitates monitoring of the power that is being delivered and consumed. As shown by FIG. 17, power control scheme or system 290 extends from connector 266 and comprises a 12 V integrated electronic fuse 301, a 12 V standby integrated electronic fuse 302, a 1.2 V linear register 303, a 3.3 V linear register 304, a 5 V standby register 305 and a 12 V/5V standby connector or header 306. In other implementations, power control system 299 may have other configurations or may be omitted.

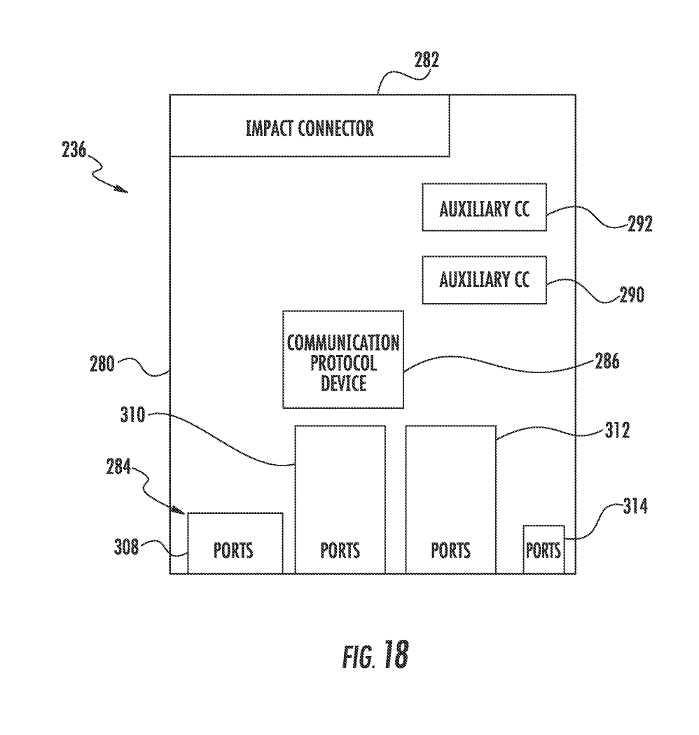

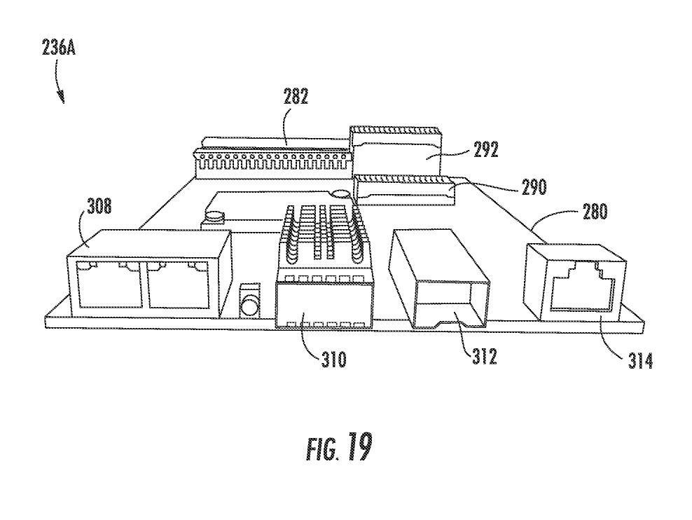

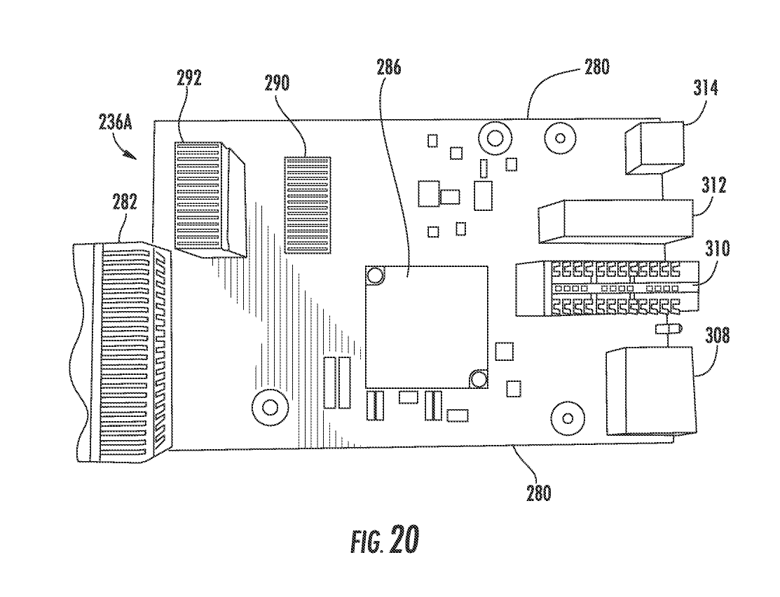

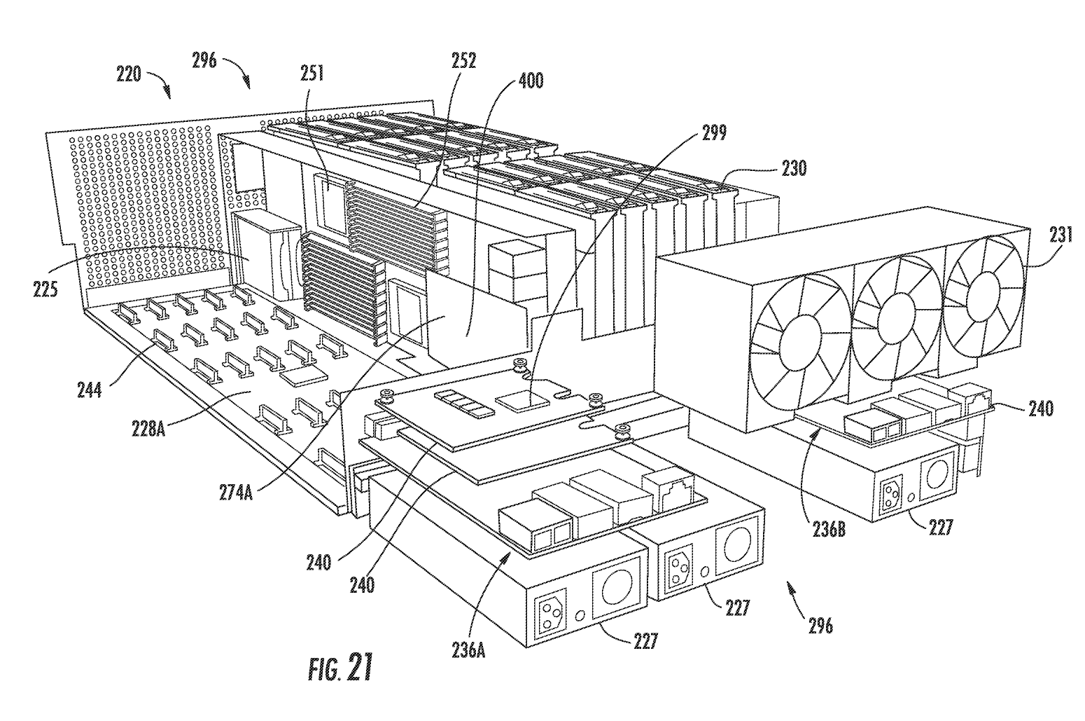

FIGS. 18-20 illustrate an example of one of input-output modules 236. Module 236 comprises a device that facilitates modularity and adaptability of inputs and outputs for server system 220. Input-output module 236 facilitates the exchange, service or upgrade of server circuit board 232 by relocating input-output interfaces and controllers for server circuit board 232 onto a separately mounted structure such that the server circuit board 232 may be exchanged, serviced or upgraded with fewer, if any, changes to the input-output architecture or layout including the associated cabling. In other words, server circuit board 232 may be upgraded, repaired or redeployed with reduced disturbance to an existing external cabling system without a loss of input-output, such as an ethernet or an InfiniBand interface component.

In addition, each module 236 further facilitate changes to the input-output for a server circuit board 232 independent of the server circuit board 232. In other words, the input-output components for a particular server circuit board may be upgraded or exchanged while the existing server circuit board 232 remains in use and in place. By relocating input-output interfaces and controllers from server circuit board 232, additional area or space is provided along server circuit board 232 for enhanced airflow and enhanced cooling of the processors or other heat generating components on server circuit board 232.

As shown by FIGS. 18-20, module 236 comprises base circuit board 280, connector 282, input-output ports 284, communication protocol device 286 and auxiliary card connectors 290, 292. Base circuit board 280 comprise a printed circuit board supporting one or more input-output interfaces and controllers as well as electrical traces for routing signals across circuit board 280. Connector 282 comprises an interface releasably connecting circuit board 280 to mid-plane 226. In one implementation, connector 282 comprises a high-frequency mid-plane impact connector.

Input-output ports 284 comprise ports by which input-output signals may be transmitted to and from module 236 from external sources. In the example illustrated, ports 284 comprise a dual 1 gigabyte RJ45 connector 308, a QSFP module, copper direct connect or fiber optic transceiver capable of supporting a 10 GB per second data transfer rate as Ethernet or 40 Gb/s when configured as INFINIBAND, an SFP+ connector 312 capable of a transferring data at 10 Gb per second Ethernet and a RJ45 serial port 314. In other implementations, ports 284 may include a fewer or greater of connectors or ports as well as alternative types of connectors or ports for facilitating the input and output of data. For example, in yet other implementations, ports 284 may comprise an InfiniBand port which is a switched fabric communication link. In yet other implementations, port 284 may comprise other presently available or future available ports or connectors supporting high rates of data transfer.

Input-output controller 286 comprises communication protocol device to transfer and format data received through ports 284 to the server chip set or in reverse from the chip set to ports 284. For example, controller 286 handles all protocol for communications through ports 284. In one implementation, controller 286 comprises a PCIe GEN3 end point with a dual 10 GB Ethernet or single 10 GB ethernet and 40 gigabyte Infiniband (IB) controller. In one implementation, controller 286 may comprise a MELLANOX CX3 Virtual Protocol Interface (VPI) device. In other implementations, controller 286 may comprise other controllers or switches.

Auxiliary connectors 290, 292 comprise connectors extending from base circuit board 280 to facilitate connection of modular control daughter cards 240 (shown in FIG. 21). In the example illustrated, connectors 290, 292 comprise mezzanine connectors for supporting daughter cards 240, respectively, in a mezzanine or stacked architecture. In the example illustrated, connectors 290, 292 comprise high-density parallel board connectors such as INFINX connectors commercially available from Amphenol. In other implementations, auxiliary connectors 290, 292 may have other configurations or may be omitted.

FIG. 21 illustrates server system 220 with portions omitted for purposes of illustration. FIG. 21 illustrates modular control daughter cards 240 (one of which is seen in FIG. 21). As shown by FIG. 21, daughter cards 240 are connected to connectors 290, 292 in the stacked or mezzanine arrangement between power supplies 227 and fans 231. As a result, daughter cards 240 facilitate efficient use of available space within enclosure 224. Each daughter card 290 includes a server-storage array controller 299. Similar to server-storage controller 99 described above, each server-storage array controller 299 comprises a device that manages physical memory devices, such as disk drives, and presents such drives to server circuit board 230 to as logical units. In the example illustrated, server-storage array controller 299 may manage a portion of hard drives 230. In one implementation, server-storage array controller 299 comprises a RAID controller. In other implementations, server-storage array controller 299 may comprise other forms of devices for managing hard drives 230 and interfacing between such hard drives 230 and server circuit board 232.

In the example illustrated in FIG. 21, like server system 20, server system 220 provides a plurality of bus segments or communication lanes, such as PCIe lanes, extending from each server-storage array controller 299 of a particular module 236, across module circuit board 280 and ultimately to an associated server circuit board 232. Server system 220 further provides a plurality of bus segments or communication lanes 400 (schematically shown), such as PCIe lanes, extending from at least one of ethernet input-output ports 284, across module circuit board 280 and ultimately to server circuit board 232. In one implementation, the plurality of communication lanes extending to the server circuit board 232 extend across an adapter, such as adapter 34 or adapter 274. In one implementation, server system 220 includes three 8 Lane PCIe bus segments from a server chipset on server circuit board 232 with 16 of the lanes connected to two array controllers 299 and eight of the lanes connected to at least one of input-output port 284. In such an implementation, a plurality of SAS lanes are also provided from each array controller 299, across a circuit board 280, across mid-plane 226 and to hard drives 230 on a memory device backplane 228. In other implementations, the number and type of lanes and the system components to which such lanes are connected may be varied.

FIG. 22 is a top plan view illustrating server system 220 modified to replace an uppermost one of daughter cards 240 with an adapter card 402 that is removably connected to base circuit board 280 of module 236B by connector 292. As shown by FIG. 22, adapter card 402 includes a PCIe slot 404 receiving a PCIe option card 406. In one implementation, module 236B may include the stacked daughter cards 240 as shown in FIG. 21. In other implementations, both modules 236 may omit one of daughter cards 240 in favor of an adapter card 402 and an associated PCIe option card 406. In still other implementations, each of modules 236 may be connected to two daughter cards 240.

Although the present disclosure has been described with reference to example embodiments, workers skilled in the art will recognize that changes may be made in form and detail without departing from the spirit and scope of the claimed subject matter. For example, although different example embodiments may have been described as including one or more features providing one or more benefits, it is contemplated that the described features may be interchanged with one another or alternatively be combined with one another in the described example embodiments or in other alternative embodiments. Because the technology of the present disclosure is relatively complex, not all changes in the technology are foreseeable. The present disclosure described with reference to the example embodiments and set forth in the following claims is manifestly intended to be as broad as possible. For example, unless specifically otherwise noted, the claims reciting a single particular element also encompass a plurality of such particular elements.

What is claimed is:

1. An apparatus comprising:
a base circuit board (80, 280) having a mid-plane connector (82, 282) for connecting the base circuit board (80, 280) to a mid-plane (26, 226) connected to a server circuit board (32, 232); and
an ethernet input/output port (84, 284) on the base circuit board (80, 280) to facilitate communication across the base circuit board (80, 280) to the server circuit board (32, 232).

2. The apparatus of claim 1 further comprising:
a first card connector (90, 92, 290, 292) extending from the base circuit board (80, 280);
a first auxiliary circuit board (38, 40, 240) releasably connected to the base circuit board (80, 280) by the first card connector (90, 92, 290, 292); and
a first server-storage controller (99, 299) on the first auxiliary circuit board (38, 40, 240).

3. The apparatus of claim 2 further comprising:
an adapter card (402) releasably connected to the base circuit board (80, 280);
a PCIe slot (404) on the adapter card (402).

4. The apparatus of claim 2, wherein the first auxiliary circuit board (38, 40, 240) comprises a PCIe mezzanine card.

5. The apparatus of claim 2 further comprising:
a second connector (90, 92, 290, 292) extending from the base circuit board (80, 280);
a second auxiliary circuit board (38, 40, 240) releasably connected to the base circuit board (80, 280) by the second connector (90, 92, 290, 292); and
a second server-storage controller (99, 299) on the second auxiliary circuit board (90, 92, 290, 292).

6. The apparatus of claim 5 further comprising:
the server circuit board (32, 232);
the mid-plane (26, 226);
a first memory device backplane (28, 228);
a first memory device (30, 230) releasably connected to the memory device backplane (28, 228);
a second memory device backplane (28, 228);
a second memory device (30, 230) releasably connected to the second memory device backplane (28, 228);
a communications protocol device (86, 286) on the base circuit board (80, 280);
a first plurality of PCIe lanes (102, 104) extending from the first server-storage controller on the first auxiliary circuit board (38, 40, 240), across the base circuit board (80, 280), across the mid-plane (26, 226) to the server circuit board (32, 232);
a second plurality of PCIe lanes (102, 104) extending from the second server-storage controller on the second auxiliary circuit board (38, 40, 240), across the base circuit board (80, 280), across the mid-plane (26, 226) to the server circuit board; and
a third plurality of PCIe lanes (106) extending from the communication protocol device (86, 286), across the base circuit board (80, 280), across the mid-plane (26, 226) to the server circuit board (32, 232).

7. The apparatus of claim 6 further comprising:
a bus slot (50, 250) on the server circuit board (32, 232);
an adapter circuit board (56, 256);
a riser (58, 258) extending from the adapter circuit board (56, 256) and received within the bus slot (50, 250) of the server circuit board (32, 232) connected to the mid-plane (26, 226) and connected to the server board (32, 232) via a riser (58, 258) extending from the adapter circuit board (56, 256) and received within the bus slot (50, 250) of the server circuit board (32, 232);
a mid-plane (26, 226) connector supported by the adapter circuit board (56, 256) and connected to the mid-plane (26, 226); and
repeaters (76, 276) on the adapter circuit board (56, 256), wherein the third plurality of PCI lanes extend from the communication protocol device, across the base circuit board (80, 280), across the mid-plane (26, 226), from the mid-plane (26, 226) to the repeaters (76, 276) on the adapter circuit board (56, 256) and extend from the repeaters (76, 276) to the server circuit board.

8. The apparatus of claim 1 further comprising:
an adapter card (402) releasably connected to the base circuit board (80, 280); and
a PCIe slot (404) on the adapter card (402).

9. The apparatus of claim 1 further comprising a first card connector (90, 92, 290, 292) extending from the base circuit board (80, 280).

10. The apparatus of claim 9 further comprising a second card connector (90, 92, 290, 292) extending from the base circuit board (80, 280).

11. The apparatus of claim 1 further comprising:
the mid-plane (26, 226);
a memory device backplane (28, 228) connected to the mid-plane (26, 226); and
a memory device (30, 230) connected to the memory device backplane (28, 228).

12. The apparatus of claim 11 further comprising a power supply (227) connected to the mid-plane (226), wherein the base circuit board (280) is connected to the mid-plane (226) and extends over the power supply (227).

13. The apparatus of claim 11 further comprising a fan (231), wherein the base circuit board (80, 280) is sandwiched between the fan (231) and the power supply (227).

14. An apparatus comprising:
a server circuit board (32, 232);
a memory device backplane (28, 228);
a memory device (30, 230) on the memory device backplane (28, 228);
a first circuit board (38, 40, 240) connected to the memory device backplane (28, 228) and the server circuit board (32, 232);
a server-storage controller (99, 299) carried by the first circuit board (38, 40, 240); and
a serial attached SCSI (SAS) lane (108) extending from the server-storage controller across the first circuit board (38, 40, 240) to the memory device (30, 230); and
a PCIe lane (102, 104) from the server-storage controller (99, 299) across the first circuit board (38, 40, 240) to the server circuit board (32, 232).

15. A method comprising:
releasably connecting a base circuit board (80, 280) directly to a mid-plane (26, 226) which is connected to a server board (32, 232); and
communicating with the server board (32, 232) across an ethernet input-output port (84, 284) located on the base circuit board (80, 280).
